(19) United States
(12) Patent Application Publication
(10) Pub. No.: US 2026/0173394 A1
(43) Pub. Date: Jun. 18, 2026

(54) VERTICAL NONVOLATILE MEMORY DEVICE, ELECTRONIC APPARATUS INCLUDING THE SAME, AND METHOD OF MANUFACTURING VERTICAL NONVOLATILE MEMORY DEVICE

(71) Applicant: Samsung Electronics Co., Ltd., Suwon-si (KR)

(72) Inventors: Hoseok HEO, Suwon-si (KR); Minhyun LEE, Suwon-si (KR); Seungdam HYUN, Suwon-si (KR); Kyunghun KIM, Suwon-si (KR); Jinjoo PARK, Suwon-si (KR)

(73) Assignee: Samsung Electronics Co., Ltd., Suwon-si (KR)

(21) Appl. No.: 19/276,851

(22) Filed: Jul. 22, 2025

(30) Foreign Application Priority Data
Dec. 16, 2024 (KR) 10-2024-0187470

(51) Int. Cl. H10B 51/30; H10B 43/27; H10B 43/35; H10B 51/20; H10D 30/01; H10D 30/69; H10D 64/68

(52) U.S. Cl. CPC H10B 51/30; H10B 43/27; H10B 43/35; H10B 51/20; H10D 30/0413; H10D 30/0415; H10D 30/693; H10D 30/701; H10D 64/689

(57) ABSTRACT

Provided is a vertical nonvolatile memory device including a plurality of cell strings. Each of the cell strings includes a channel layer, a charge tunneling layer, a charge storage layer, and a charge blocking layer that are sequentially arranged in a transverse direction perpendicular to a longitudinal direction. The charge storage layer includes a first layer and a second layer including a nitride ferroelectric.

### CROSS-REFERENCE TO RELATED APPLICATION

This application is based on and claims priority under 35 U.S.C. § 119 to Korean Patent Application No. 10-2024-0187470, filed on Dec. 16, 2024, in the Korean Intellectual Property Office, the disclosure of which is incorporated by reference herein in its entirety.

### BACKGROUND

### 1. Field

The disclosure relates to a vertical nonvolatile memory device, an electronic apparatus including the vertical nonvolatile memory device, and a method of manufacturing the vertical nonvolatile memory device.

### 2. Description of the Related Art

Nonvolatile memory devices include a plurality of memory cells configured to retain stored information even when power supply is interrupted, allowing the stored information to be accessed again once power is restored. Such nonvolatile memory devices may be widely applied to cellular phones, digital cameras, personal digital assistants (PDAs), portable computing apparatuses, and/or the like.

Recently, vertical NAND (VNAND) flash memory devices, in which a plurality of memory cells are stacked in a vertical direction, have been developed in response to demands for higher integration. Vertical NAND flash memory devices are required to have relatively low operating voltage and relatively high charge retention.

### SUMMARY

Provided are a memory device with a reduced operating voltage, an electronic apparatus including the memory device, and a method of manufacturing the memory device.

Provided are a memory device with improved charge retention, an electronic apparatus including the memory device, and a method of manufacturing the memory device.

Additional aspects will be set forth in part in the description which follows and, in part, will be apparent from the description, or may be learned by practice of the presented embodiments of the disclosure.

According to an aspect of the disclosure, a vertical nonvolatile memory device includes a plurality of cell strings, each of the plurality of cell strings includes a plurality of layers including a channel layer, a charge tunneling layer, a charge storage layer, and a charge blocking layer sequentially arranged in a transverse direction perpendicular to a longitudinal direction such that the charge blocking layer is an outer most layer of the plurality of layers, the transverse direction, a plurality of gate electrodes that are located outside the charge blocking layer and arranged in the longitudinal direction, and a plurality of isolation layers arranged in the longitudinal direction and isolating the plurality of gate electrodes from each other. The charge storage layer includes a first layer including Si and N, and a second layer including a nitride ferroelectric.

In at least one example embodiment, the nitride ferroelectric may include at least one selected from AlN, ZnSiN₂, or MgSiN₂.

In at least one example embodiment, the nitride ferroelectric may include AlN, and the second layer may be doped with at least one dopant selected from Sc, B, Sn, Ga, Hf, Zr, or Ti.

In at least one example embodiment, a content of the at least one dopant in the second layer may be 40% or less.

In at least one example embodiment, a content of the at least one dopant in the second layer may be about 5% to about 20%.

In at least one example embodiment, the second layer may have a wurtzite structure.

In at least one example embodiment, a thickness of the second layer may be about 15% to about 50% of a thickness of the charge storage layer.

In at least one example embodiment, the second layer may be between the charge tunneling layer and the first layer.

In at least one example embodiment, the second layer may be between the charge blocking layer and the first layer.

In at least one example embodiment, the charge storage layer may include two or more of the second layers, and one of the second layers may be between the charge tunneling layer and the first layer and another of the second layers may be between the charge blocking layer and the first layer.

In at least one example embodiment, the second layer may be provided within the first layer such that the second layer is not in contact with either the charge tunneling layer or the charge blocking layer.

In at least one example embodiment, the first layer may form an amorphous matrix, and the nitride ferroelectric may form a plurality of nanostructures.

In at least one example embodiment, the plurality of nanostructures may be apart from each other.

In at least one example embodiment, the plurality of nanostructures may have a wurtzite structure.

In at least one example embodiment, the amorphous matrix may include Si, N, Al, and at least one dopant selected from Sc, B, Sn, Ga, Hf, Zr, or Ti, and the nitride ferroelectric may include Al and N and at least one dopant selected from Sc, B, Sn, Ga, Hf, Zr, or Ti.

In at least one example embodiment, a content of the at least one dopant in the second layer may be 40% or less.

In at least one example embodiment, a content of the at least one dopant in the second layer may be about 5% to about 20%.

According to an aspect of the disclosure, an electronic apparatus includes a memory and a memory controller configured to control the memory to read data from the memory and/or to write data to the memory, wherein the memory includes the vertical nonvolatile memory device.

According to an aspect of the disclosure, a method of manufacturing a memory device includes alternately stacking insulating layers and conductive layers on a substrate, forming a channel hole through the insulating layers and the conductive layers, and forming a charge blocking layer in the channel hole; forming a charge storage layer on an inner wall of the charge blocking layer; forming a charge tunneling layer on the charge storage layer; and forming a channel layer on the charge tunneling layer. The forming of the charge storage layer includes forming a mixture layer on an inner wall of the charge blocking layer, the mixture layer including Si, N, Al, and at least one dopant selected from Sc, B, Sn, Ga, Hf, Zr, or Ti, and forming a first layer and a second layer by heat treating the mixture layer. The first layer includes an amorphous matrix including Si, N, Al, and at least one dopant selected from Sc, B, Sn, Ga, Hf, Zr, and Ti. The second layer includes a plurality of nanostructures apart from each other. The plurality of nanostructures has a wurtzite structure including Al, N, and at least one dopant selected from Sc, B, Sn, Ga, Hf, Zr, and Ti. The second layer is within the amorphous matrix such that the second layer is not in contact with either the charge tunneling layer or the charge blocking layer.

In at least one example embodiment, a content of the at least one dopant in the second layer may be 40% or less.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view illustrating a vertical nonvolatile memory device according to at least one example embodiment;

FIG. 2 is a cross-sectional view taken along line A-A′ of FIG. 1;

FIG. 3 is an enlarged view illustrating a portion D1 in FIG. 2;

FIG. 4 is a schematic cross-sectional view illustrating a vertical nonvolatile memory device according to at least one example embodiment, corresponding to FIG. 3;

FIG. 5 is a schematic cross-sectional view illustrating a vertical nonvolatile memory device according to at least one example embodiment, corresponding to FIG. 3;

FIG. 6 is a schematic cross-sectional view illustrating a vertical nonvolatile memory device according to at least one example embodiment, corresponding to FIG. 3;

FIG. 7 is a schematic cross-sectional view illustrating a vertical nonvolatile memory device according to at least one example embodiment, corresponding to FIG. 2;

FIG. 8 is an enlarged view illustrating a portion D2 in FIG. 7;

FIG. 9 is a circuit diagram including a vertical nonvolatile memory device according to at least one example embodiment;

FIGS. 10A to 10F are views illustrating a method of manufacturing a vertical nonvolatile memory device, according to at least one example embodiment;

FIG. 11 is a schematic block diagram illustrating a display driver integrated circuit (display driver IC or DDI) and a display apparatus including the DDI, according to at least one example embodiment;

FIG. 12 is a block diagram illustrating an electronic apparatus according to at least one example embodiment;

FIG. 13 is a block diagram illustrating an electronic apparatus according to at least one example embodiment; and

FIGS. 14 and 15 are conceptual diagrams schematically illustrating device architectures applicable to an electronic apparatus, according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, vertical nonvolatile memory devices and electronic apparatuses including the vertical nonvolatile memory devices will be described according to various embodiments with reference to the accompanying drawings. In the drawings, like reference numerals refer to like elements, and the sizes of elements may be exaggerated for clarity of illustration. Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Although the terms “first,” “second,” etc. may be used herein to describe various components, these components should not be limited by these terms. These terms are only used to distinguish one element from another.

The terms of a singular form may include plural forms unless otherwise mentioned. It will be further understood that the terms “comprises” and/or “comprising” used herein specify the presence of stated features or elements, but do not preclude the presence or addition of one or more other features or elements. In the drawings, the sizes of elements may be exaggerated for clarity of illustration. In addition, when a material layer is referred to as being “above” or “on” a substrate or another layer, it may be directly on the substrate or the other layer while making contact with the substrate or the other layer or may be above the substrate or the other layer with a third layer therebetween. Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

In the following descriptions of the embodiments, a material of each layer is merely an example, and another material may be used.

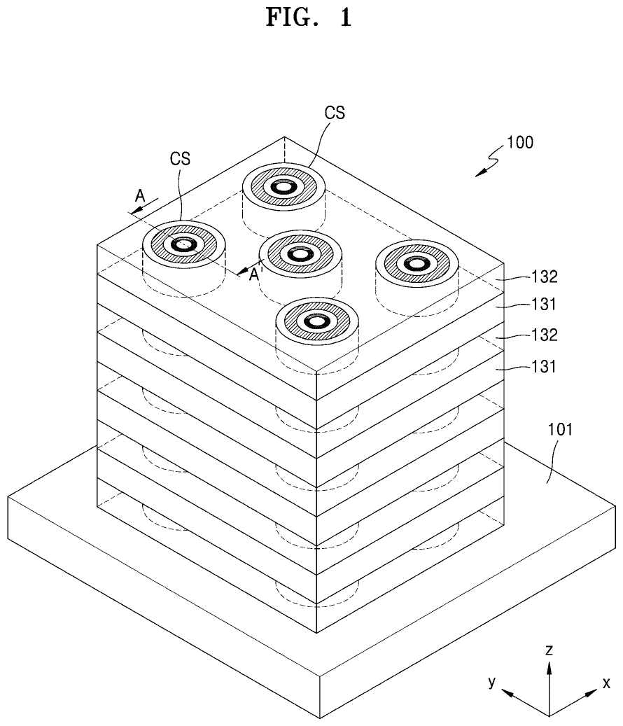

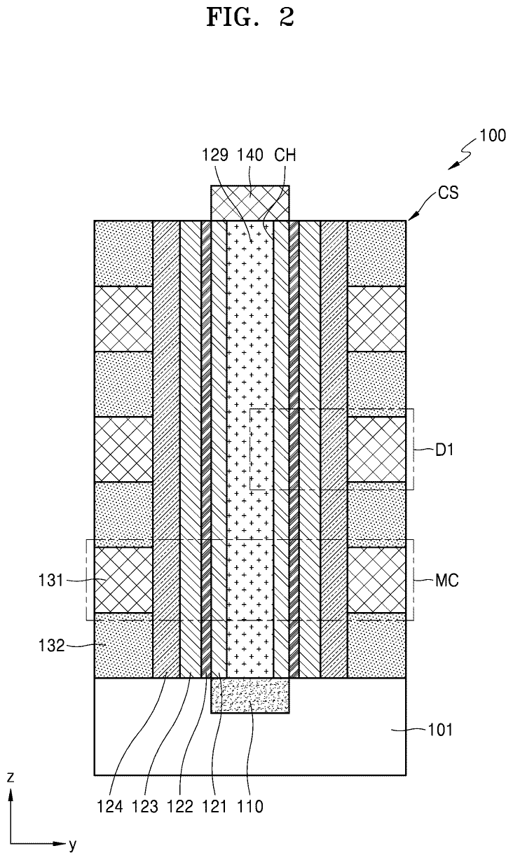

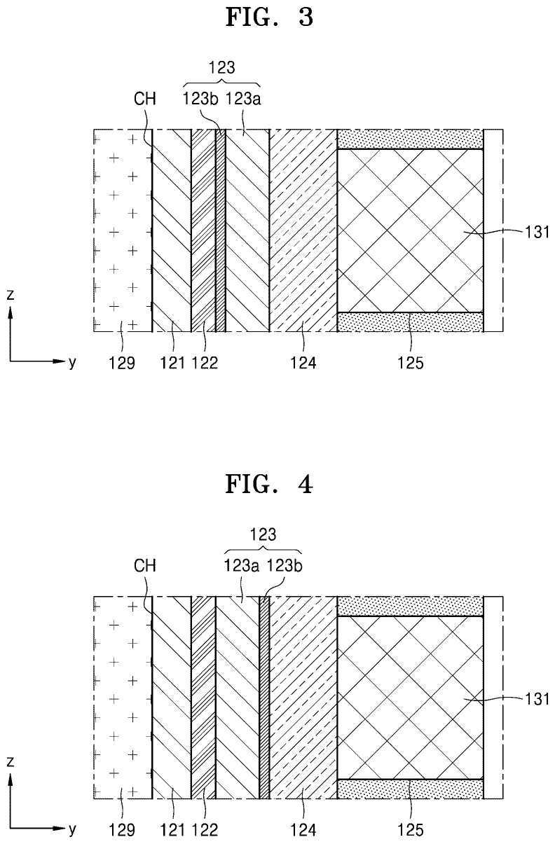

FIG. 1 is a schematic perspective view illustrating a vertical nonvolatile memory device 100 according to at least one example embodiment. FIG. 2 is a cross-sectional view taken along line A-A′ of FIG. 1. FIG. 3 is an enlarged view illustrating a portion D1 in FIG. 2.

The vertical nonvolatile memory device 100, according to some examples, includes a plurality of cell strings CS disposed on a substrate 101. The cell strings CS extend in a longitudinal direction (z-axis direction in FIG. 1) that is perpendicular to the substrate 101. The cell strings CS may be arranged on the substrate 101 in various forms. For example, the cell strings CS may be arranged in staggered rows, staggered columns, in an array including aligned rows and columns, and/or the like. Gate electrodes 131 and isolation layers 132 may be alternately stacked on the substrate 101.

Each of the cell strings CS may include a channel hole CH penetrating a stacked structure of the gate electrodes 131 and the isolation layers 132 in the longitudinal direction z. For example, the channel hole CH may have a circular cross-sectional shape. However, the cross-sectional shape of the channel hole CH is not limited thereto. In each of the cell strings CS, regions other than the gate electrodes 131 and the isolation layers 132 may have a structure in which a plurality of material layers are stacked outward from the channel hole CH in a cylindrical shell shape in transverse directions (x-axis and y-axis directions) that are perpendicular to the longitudinal direction z. The material layers stacked in the cylindrical shell shape form memory cells MC. For example, each of the cell strings CS includes a plurality of memory cells MC arranged in the z-axis direction. Some of the material layers forming each of the memory cells MC are separated from corresponding material layers of other memory cells MC in the z-axis direction by the isolation layers 132. However, the structure of the cell strings CS is not limited thereto and may have other forms and structures.

The substrate 101 may be or include a semiconductor substrate, such as at least one a single-crystal silicon substrate, a compound semiconductor substrate, or a silicon-on-insulator (SOI) substrate, but is not limited thereto. The substrate 101 may further include at least one of dopant regions formed by doping, electronic elements such as transistors, or a peripheral circuit configured to select and control memory cells that store data.

Each of the cell strings CS, according to some example embodiments, includes a plurality of memory cells MC stacked on the substrate 101 in a direction (z-axis direction) perpendicular to the substrate 101. The memory cells MC may each be a basic unit cell for writing and erasing data. Each of the cell strings CS may include a channel layer 121, a charge tunneling layer 122, a charge storage layer 123, a charge blocking layer 124, and the gate electrodes 131. The gate electrodes 131 are isolated from each other in the longitudinal direction z by the isolation layers 132. The gate electrodes 131 face the channel layer 121, the charge tunneling layer 122, the charge storage layer 123, and the charge blocking layer 124 in the transverse directions. Each of the memory cells MC is formed by a gate electrode 131 and regions of the channel layer 121, the charge tunneling layer 122, the charge storage layer 123, and the charge blocking layer 124 facing the gate electrode 131. In each of the cell strings CS of the embodiment, the memory cells MC share the channel layer 121, the charge tunneling layer 122, the charge storage layer 123, and the charge blocking layer 124.

The charge tunneling layer 122 is provided on an outer side of the channel layer 121 in the transverse directions perpendicular to the longitudinal direction z. For example, the charge tunneling layer 122 may surround an outer transversal surface of the channel layer 121 and extend in the longitudinal direction z. The charge storage layer 123 is provided on an outer side of the charge tunneling layer 122 in the transverse directions. For example, the charge storage layer 123 may surround an outer transversal surface of the charge tunneling layer 122 and extend in the longitudinal direction z-axis direction. The charge blocking layer 124 is arranged on an outer side of the charge storage layer 123 in the transverse directions. For example, the charge blocking layer 124 may surround the charge storage layer 123 and extend in the longitudinal direction z-axis direction. The gate electrodes 131 are arranged apart from each other in the longitudinal direction z-axis direction at an outer transversal side of the charge blocking layer 124 and are isolated from each other in the longitudinal direction z by the isolation layers 132.

A source electrode 110 and a drain electrode 140 are respectively arranged at both ends of the channel layer 121 in the longitudinal direction z. The source electrode 110 may be commonly connected to the cell strings CS. When a voltage is applied to a gate electrode 131 of a memory cell MC, a channel may be formed in an inner region of the channel layer 121 that is opposite the gate electrode 131, and a charge flowing between the source electrode 110 and the drain electrode 140 may tunnel through the charge tunneling layer 122 and be trapped in the charge storage layer 123, thereby storing information.

The channel layer 121 may include a semiconductor material. The channel layer 121 may include, for example, at least one of Si, Ge, SiGe, a Group III-V semiconductor material, or the like. In addition, the channel layer 121 may include, for example, at least one of an oxide semiconductor, a nitride semiconductor, an oxynitride semiconductor, a two-dimensional (2D) semiconductor material, quantum dots (QDs), or an organic semiconductor. Here, the oxide semiconductor may include, for example, InGaZnO. The 2D semiconductor material may include, for example, at least one of a transition metal dichalcogenide (TMD) or graphene, and the QDs may include at least one of colloidal QDs or nanocrystal QDs. The 2D semiconductor material refers to a semiconductor material with a 2D crystal structure and may have a monolayer structure or a multilayer structure. The 2D semiconductor material exhibits electrical properties and maintains relatively high mobility without significant changes in characteristics even when the thickness of the 2D material is reduced to the nanoscale. Thus, the 2D semiconductor material may be applied to various devices. Each layer of the 2D semiconductor material may have an atomic-level thickness. The channel layer 121 may include about one to about ten layers of the 2D semiconductor material.

The 2D semiconductor material may include at least one selected from graphene, black phosphorus, and a transition metal dichalcogenides (TMD). Graphene is a material in which carbon atoms are two-dimensionally bonded to each other in a hexagonal honeycomb structure. Graphene has higher electrical mobility, better thermal properties, better chemical stability, and larger surface area in comparison to silicon (Si). Black phosphorus is a material in which phosphorus atoms are two-dimensionally bonded to each other and appears black in color. TMD may be expressed as MX₂, where M refers a transition metal and X refers to a chalcogen element. For example, M may include at least one of Mo, W, Nb, V, Ta, Ti, Zr, Hf, Tc, or Re, and X may include at least one of S, Se, or Te. Thus, for example, TMD may include at least one of MoS₂, MoSe₂, MoTe₂, WS₂, WSe₂, Wte₂, ZrS₂, ZrSe₂, HfS₂, HfSe₂, NbSe₂, or ReSe₂.

Alternatively, the 2D semiconductor material may include CuS, which is a compound of a transition metal, copper (Cu), and a chalcogen element, sulfur (S). In addition, the 2D semiconductor material may be a chalcogenide material including a non-transition metal. The non-transition metal may include, for example, at least one of Ga, In, Sn, Ge, or Pb. In this case, the 2D semiconductor material may include a compound of a non-transition metal such as at least one of Ga, In, Sn, Ge, or Pb, and a chalcogen element such as at least one of S, Se, or Te. For example, the 2D semiconductor material may include at least one of SnSe₂, GaS, GaSe, GaTe, GeSe, In₂Se₃, or InSnS₂. However, the materials mentioned above are only examples, and other materials may also be used as 2D semiconductor materials.

The channel layer 121 may further include a dopant. Here, the dopant may include a p-type dopant or an n-type dopant. The p-type dopant may include, for example, a Group III element such as at least one of B, Al, Ga, or In, and the n-type dopant may include, for example, a Group V element such as at least one of P, As, or Sb.

In at least one example embodiment, the channel layer 121 has a cylindrical shape. Therefore, the channel hole CH is provided inside the channel layer 121. A pillar 129 may be filled in the channel hole CH. The pillar 129 may include, for example, silicon oxide (SiO₂) or air, but is not limited thereto.

The charge tunneling layer 122 is arranged between the channel layer 121 and the charge storage layer 123 for charge tunneling between the channel layer 121 and the charge storage layer 123. For example, the charge tunneling layer 122 may include an insulator, such as at least one of silicon oxide or a metal oxide but is not limited thereto. For example, the charge tunneling layer 122 includes silicon oxide.

The charge storage layer 123 is configured to store charge introduced thereto. Charges (for example, electrons) present in the channel layer 121 may be introduced into the charge storage layer 123 via tunneling effects or the like. The charges introduced into the charge storage layer 123 may be trapped in the charge storage layer 123. The charge storage layer 123 may include a ferroelectric materials, as discussed in further detail below.

The charge blocking layer 124 may function as a barrier to prevent (or hinder) charge movement between the charge storage layer 123 and the gate electrodes 131. A surface of the charge blocking layer 124 may be in contact with the charge storage layer 123, and another surface of the charge blocking layer 124 may be in contact with the gate electrodes 131. The charge blocking layer 124 may include an insulator, such as at least one of silicon oxide, a metal oxide, or a metal nitride, but is not limited thereto. The charge blocking layer 124 may include at least one selected from aluminum oxide (AlO), magnesium oxide (MgO), aluminum nitride (AlN), and gallium nitride (GaN).

The gate electrodes 131 may control corresponding regions of the channel layer 121. Word lines may be electrically connected to the gate electrodes 131. The gate electrodes 131 may include one or more of a highly conductive metal material, a conductive oxide, a metal nitride, silicon doped with a dopant, or a 2D conductive material. The metal material may include, for example, at least one of Au, Ti, TiN, TaN, W, Mo, WN, Pt, Nb, NbN, Ni, and/or any combination thereof. The conductive oxide may include, for example, at least one of indium tin oxide (ITO), indium zinc oxide (IZO), or the like. However, these materials are only examples, and the gate electrodes 131 may include other various materials.

The isolation layers 132 function as spacers that isolate the gate electrodes 131 from each other in the longitudinal direction z. The isolation layers 132 may include an insulator, for example, at least one of silicon oxide, silicon nitride, or the like, but are not limited thereto. For example, the isolation layers 132 includes silicon oxide.

Improvements to nonvolatile memory (NVM) devices may include the NVM devices having a relatively low operating voltage (that is, program/erase voltages), a large memory window (the difference between the program voltage and the erase voltage), and a relatively high charge retention. A method of lowering an operating voltage by using a ferroelectric material such as an oxide ferroelectric as a charge storage layer and controlling the degree of polarization within the ferroelectric material according to a voltage applied to the ferroelectric material may be considered as a method of implementing a lower-power operation. However, controlling the crystal phase of oxide ferroelectrics is complex due to polymorphism. For example, hafnium oxide (HfO) may have various crystal phases such as orthorhombic phase, monoclinic phase, tetragonal phase, and cubic phase, depending on factors such as temperature, pressure, and impurity concentration during manufacturing processes. Among such crystal phases, only the orthorhombic phase exhibits ferroelectricity, and the other phases do not exhibit ferroelectricity. Thus, during manufacturing processes, precise control of temperature, pressure, and impurity concentration is generally required to ensure the formation of orthorhombic-phase hafnium oxide. Furthermore, orthorhombic-phase hafnium oxide exists in a thermodynamically metastable state with a relatively low thermal budget, and thus, maintaining a stable orthorhombic phase under thermal conditions of memory device manufacturing processes is difficult.

In addition, oxide ferroelectrics may form an interlayer oxide at an interface with an adjacent material layer due to oxidation reactions. This phenomenon is known to be caused by the diffusion of oxygen positive holes within oxide ferroelectrics. For example, when an oxide ferroelectric forms an interface with a material layer containing Si, a silicon oxide layer is formed between the oxide ferroelectric and the material layer. Due to the difference between polarization-induced charge density of the oxide ferroelectric and the charge density of the adjacent material layer containing Si, a strong electric field is applied to the silicon oxide layer. As a result, issues such as leakage current and device breakdown may occur. Furthermore, due to a relatively high interface trap charge density of the silicon oxide layer, issues such as trap-assisted polarization switching, endurance degradation, and read-after-write delay may occur.

According to the disclosure, in order to address the above issues, the charge storage layer 123 may include a first layer 123a and a second layer 123b. The first layer 123a may include Si and N. For example, the first layer 123a may include SiN. In at least some embodiments, the first layer 123a may further include oxygen. The second layer 123b may include a nitride ferroelectric. Here, the term “nitride ferroelectric” encompasses both “nitride ferroelectric” and “nitride antiferroelectric” and will be used in this meaning throughout the description. The second layer 123b forms an interface with the first layer 123a. The second layer 123b may be arranged in at least one of a region between the first layer 123a and the charge tunneling layer 122 and/or a region between the first layer 123a and the charge blocking layer 124. For example, in FIG. 3, the second layer 123b is arranged between the first layer 123a and the charge tunneling layer 122.

When the vertical nonvolatile memory device 100 operates, for example, when a program voltage V_{PGM} is applied to the vertical nonvolatile memory device 100 for programming, polarization switching occurs in the second layer 123b due to ferroelectric switching, and the second layer 123b exhibits a relatively high permittivity. Most of the applied program voltage V_{PGM} is applied between the first layer 123a and the charge tunneling layer 122, and positive or negative charges generated by the polarization of the second layer 123b further amplify an electric field applied between the first layer 123a and the charge tunneling layer 122. As a result, charges (electrons) may easily move from the channel layer 121 to the charge storage layer 123 through the charge tunneling layer 122 and stay in the charge storage layer 123. Because the voltage required for charges (electrons) to tunnel through the charge tunneling layer 122 is fixed, the program voltage V_{PGM} may be reduced. The mechanism for erasing is the same as the mechanism for programming, except that tunneling charges are holes instead of electrons. Therefore, an erase voltage V_{ERS} may also be reduced. In addition, the memory window of the vertical nonvolatile memory device 100 may be improved.

The crystal phase of nitride ferroelectrics includes two structures: wurtzite and hexagonal, and the wurtzite structure exhibits ferroelectricity. The wurtzite structure has a relatively high thermal stability and may thus remain stable during memory device manufacturing processes. Therefore, compared to oxide ferroelectrics, nitride ferroelectrics are easier to manufacture.

In general, during a process of forming a SiN layer, a silicon oxide layer having a thickness of, for example, 1.0 nanometers (nm) or less may form on a surface of the SiN layer due to oxidation. In this state, when an oxide ferroelectric layer forms an interface with the SiN layer, additional silicon oxide may form at the interface between the SiN layer and the oxide ferroelectric layer due to the diffusion of oxygen positive holes in the oxide ferroelectric layer. As a result, the thickness of the silicon oxide layer may increase to about 1.8 nm to about 2.0 nm. According to at least one example embodiment, the second layer 123b including a nitride ferroelectric forms an interface with the first layer 123a including SiN. Because the nitride ferroelectric restricts the diffusion of oxygen positive holes during manufacturing processes, an additional increase in the thickness of a silicon oxide layer may be limited at an interface between the first layer 123a and the second layer 123b. Therefore, issues, such as an operating voltage increase caused by an interface layer (that is, a silicon oxide layer), trap-assisted polarization switching caused by trapped interfacial charges, endurance degradation, and read-after-write delay, may be protected against.

The permittivity of the nitride ferroelectric may be equivalent to or lower than the permittivity of a material, such as SiN, included in the first layer 123a. The bandgap energy of the nitride ferroelectric may be equivalent to or less than the bandgap energy of a material, such as SiN, included in the first layer 123a. The conduction band offset (CBO) of the nitride ferroelectric may be greater than the CBO of a material, such as SiN, included in the first layer 123a. As a result, the program voltage V_{PGM} may be reduced. The valence band offset (VBO) of the nitride ferroelectric may be less than the VBO of Si included in the first layer 123a. As a result, the erase voltage V_{ERS} may be reduced.

In at least one example embodiment, the nitride ferroelectric may include at least one of AlN, ZnSiN₂, or MgSiN₂.

In at least one example embodiment, when the nitride ferroelectric includes AlN, the second layer 123b may be doped with at least one dopant to enhance ferroelectricity or antiferroelectricity. The at least one dopant may include, for example, at least one of Sc, B, Sn, Ga, Hf, Zr, or Ti. When the at least one dopant includes B or Sc, ferroelectricity may be enhanced. When the at least one dopant includes Sn, antiferroelectricity may be enhanced. When the at least one dopant includes at least one of Zr, Hf, or Ti, piezoelectric modulus may be improved. The content of the at least on dopant in the second layer 123b having a wurtzite structure may be determined such that the second layer 123b may exhibit appropriate ferroelectricity or antiferroelectricity. For example, the content of the at least one dopant in the second layer 123b having a wurtzite structure may be 40% or less. For example, the content of the at least one dopant in the second layer 123b having a wurtzite structure may be from about 5% to about 20%. In other words, when Al is expressed as A, the at least one dopant is expressed as D, and nitrogen is expressed as N, the material included in the second layer 123b may be expressed as A_{1-R}D_{R}N. In this case, for example, R may be less than or equal to 0.4 (R≤0.4). In addition, for example, R may be from about 0.05 to about 0.2 (about 0.05≤R≤about 0.2).

The thickness of the second layer 123b relative to the thickness of the charge storage layer 123 may be determined such that the operating voltage reduction effect of the second layer 123b and the charge storage function of the first layer 123a may be appropriately balanced. For example, the thickness of the second layer 123b may be about 15% to about 50% of the thickness of the charge storage layer 123. For example, the thickness of the second layer 123b may be about 15% to about 30% of the thickness of the charge storage layer 123. When the thickness of the second layer 123b is less than 15% of the thickness of the charge storage layer 123, the operating voltage reduction effect may not be sufficient. In addition, when the thickness of the second layer 123b exceeds 50% of the thickness of the charge storage layer 123, the thickness of the first layer 123a is too small, and thus, a sufficient charge storage effect may not be achieved.

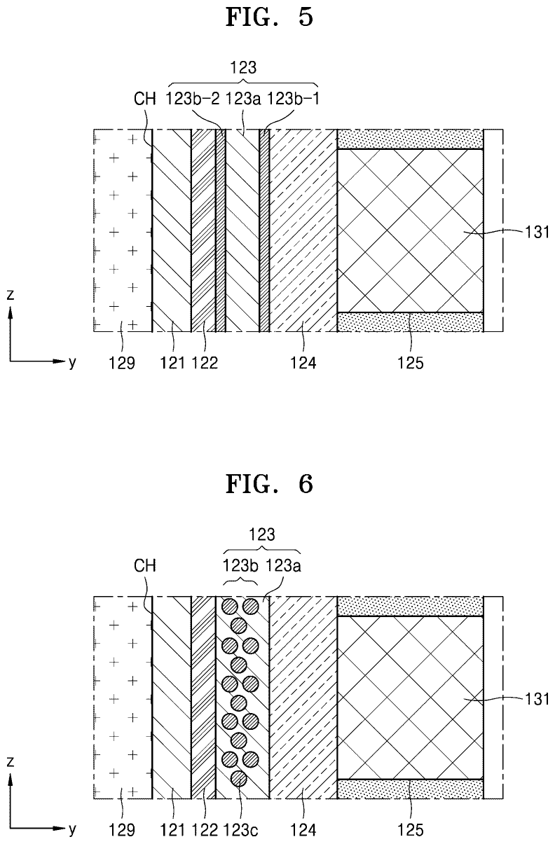

The position of the second layer 123b is not limited to the example shown in FIG. 3. The second layer 123b may be arranged at various positions as long as the second layer 123b forms an interface with the first layer 123a. For example, FIG. 4 is a schematic cross-sectional view illustrating a vertical nonvolatile memory device according to at least one example embodiment, corresponding to FIG. 3; and FIG. 5 is a schematic cross-sectional view illustrating a vertical nonvolatile memory device according to at least one example embodiment, corresponding to FIG. 3. Referring to FIG. 4, a second layer 123b may be arranged between a charge blocking layer 124 and a first layer 123a. Referring to FIG. 5, a second layer 123b-2 may be arranged between a charge tunneling layer 122 and a first layer 123a, and another second layer 123b-1 may be arranged between a charge blocking layer 124 and the first layer 123a.

The second layers 123b, 123b-1, and 123b-2, which forms charge storage layers 123 as shown in FIGS. 3 to 5, may be formed using various manufacturing processes such as sputtering, metal-organic chemical vapor deposition (MOCVD), atomic layer deposition (ALD), and thermal atomic layer deposition (THALD). The composition of the second layer 123b may be adjusted by controlling the vapor pressures of a target, a dopant, and precursors thereof during manufacturing processes. For example, when Al_{1-R}Sc_{R}N (AlN doped with Sc) is formed as a second layer 123b by sputtering, AlN formed by sputtering has a wurtzite structure. Although ScN has a preferential hexagonal phase, Al_{1-R}Sc_{R}N may maintain a wurtzite structure when R is about 0.4 (that is, when the content of Sc is about 40 at %). For example, Al_{1-R}B_{R}N may maintain a wurtzite structure when R is about 0.2 (that is, when the content of B is about 20 at %). For example, a uniform nitride ferroelectric may be formed in a relatively high-selectivity 3D structure by using ALD. In addition, the crystallinity of the second layer 123b may be improved while reducing impurities such as carbon and oxygen by using THALD, which utilizes the chemical reaction of Al and dopant halides with NH₃.

FIG. 6 is a schematic cross-sectional view illustrating a vertical nonvolatile memory device according to at least one example embodiment, corresponding to FIG. 3. Referring to FIG. 6, according to at least one example embodiment, a charge storage layer 123 has a structure in which a second layer 123b is positioned inside a first layer 123a such that the second layer 123b is not in contact with either a charge tunneling layer 122 and/or a charge blocking layer 124. The first layer 123a forms a matrix. A nitride ferroelectric forms a plurality of nanostructures 123c. The nanostructures 123c have a wurtzite structure. The nanostructures 123c are physically apart from each other. For example, the nanostructures 123c are dispersed inside the first layer 123a, that is, the matrix, such that the nanostructures 123c may not be in contact with the charge tunneling layer 122 and the charge blocking layer 124. In other words, the second layer 123b forms an insertion layer embedded inside the first layer 123a for being apart from the charge tunneling layer 122 and the charge blocking layer 124. The first layer 123a, that is, the matrix, may have an amorphous structure, and the nanostructures 123c may have a crystalline structure and/or an amorphous structure. For example, a portion of the nanostructures 123c may not have crystallized during a phase separation, and thereby may have an amorphous structure. When the nanostructures 123c have a crystalline structure, the nanostructures 123c may be referred to as nanocrystals. The nanostructures 123c may have various shapes, such as at least one of a spherical shape, an elliptical shape, a disk shape, a rod shape, or an irregular shape.

The first layer 123a, that is, the amorphous matrix, may include Si, N, Al, and at least one dopant selected from Sc, B, Sn, Ga, Hf, Zr, and Ti. The nitride ferroelectric may include Al and N and at least one dopant selected from Sc, B, Sn, Ga, Hf, Zr, and Ti. For example, the nitride ferroelectric may include a doped AlN. The charge storage layer 123 of this type may be formed by spinodal decomposition and nucleation growth through heat treatment of a mixture of Al, Si, N, and at least one dopant selected from Sc, B, Sn, Ga, Hf, Zr, and Ti.

The first layer 123a and the second layer 123b have different dopant contents. The dopant content of the first layer 123a, that is, the amorphous matrix, may be determined such that the amorphous matrix may exhibit general dielectric properties. The dopant content of the second layer 123b is determined such that the permittivity of the second layer 123b may be greater than the permittivity of the first layer 123a. In addition, the CBO of the first layer 123a relative to the charge tunneling layer 122 is greater than the CBO of the nanostructures 123c relative to the charge tunneling layer 122. Similarly, the VBO of the first layer 123a relative to the charge tunneling layer 122 is greater than the VBO of the nanostructures 123c relative to the charge tunneling layer 122. The first layer 123a, which has a relatively great CBO and VBO, exhibits charge-blocking characteristics.

When the at least one dopant includes B or Sc, ferroelectricity may be enhanced. When the at least one dopant includes Sn, antiferroelectricity may be enhanced. When the at least one dopant includes at least one of Zr, Hf, or Ti, piezoelectric modulus may be improved. The content of the at least one dopant in the second layer 123b having a wurtzite structure may be determined such that the second layer 123b may exhibit appropriate ferroelectricity or antiferroelectricity. For example, the content of the at least one dopant in the second layer 123b having a wurtzite structure may be 40% or less. For example, the content of the at least one dopant in the second layer 123b having a wurtzite structure may be about 5% to about 20%. In other words, when Al is expressed as A, the at least one dopant is expressed as D, and nitrogen is expressed as N, a material included in the second layer 123b may be expressed as A_{1-R}D_{R}N. Here, R may satisfy: R≤0.4, and/or satisfy about 0.05≤R≤about 0.2.

A key reliability factor in vertical nonvolatile memory devices is data retention, that is, the ability to retain charge in the charge storage layer 123 for an extended period. The vertical nonvolatile memory device has a structure in which memory cells MC are connected to each other in a vertical direction, that is, a longitudinal direction z. When information is stored, charges may diffuse in the longitudinal direction z and move to adjacent memory cells MC, and thus, operations of the adjacent memory cells MC may be affected. In the vertical nonvolatile memory device having a structure in which a plurality of memory cells MC in a single cell string CS share the charge storage layer 123, that is, a structure in which the charge storage layer 123 extends the same length as the channel layer 121, reducing the distance between the memory cells MC to increase memory density may cause charge migration between the memory cells MC, which may result in degradation of charge retention characteristics.

In directions perpendicular to the charge storage layer 123, that is, an x-axis direction and/or a y-axis direction, charges may move from the charge storage layer 123 to the charge tunneling layer 122 by trap-assisted tunneling or thermal emission. The degree of such charge movement may be determined by a CBO at an interface between the charge storage layer 123 and the charge tunneling layer 122.

In a direction parallel to the charge storage layer 123, that is, the longitudinal direction (z, charge movement may occur due to lateral migration caused by the gradient of charge concentration. Charge movement in the direction parallel to the charge storage layer 123 may be governed by Poole-Frenkel tunneling. Current density by Poole-Frenkel tunneling may be expressed by the following Poole-Frenkel Conduction Equation (Equation 1):

$$J = q μ {N}_{c} E exp ( \frac{- q ( {E}_{T} - \sqrt{qE / πε} )}{kT} ) \qquad ( equation 1 )$$

In equation 1, J: current density, q: electronic charge, μ: carrier mobility, N_{c}: density of states in conduction band, E: electric field, E_{T}: trap energy, ε: permittivity, k: Boltzmann constant, T: temperature.

Charge movement in the direction parallel to the charge storage layer 123 by Poole-Frenkel tunneling may be determined by trap energy E_{T} and trap density N_{T} within the charge storage layer 123. Trap energy refers to a voltage barrier that an electron must overcome to move from one atom to another within a material. That is, trap energy refers to the depth of a trap state relative to the conduction band minimum (CBM) of a material. Trap density refers to the number of trapped charges per unit volume. Trap density may be calculated using a charge pumping method. Charge retention characteristics in the direction parallel to the charge storage layer 123 may be improved by increasing the trap energy and trap density.

In the at least some example embodiments, the charge storage layer 123 has a structure in which the second layer 123b including a ferroelectric material is inserted in the first layer 123a.

Therefore, compared to the case in which a charge storage layer includes only the first layer 123a, the overall permittivity of the charge storage layer 123 is increased, and thereby the capacitance of the vertical nonvolatile memory device may be improved. Thus, the memory window of the vertical nonvolatile memory device may also be improved.

In at least one example embodiment, the charge storage layer 123 includes the nanostructures 123c inserted in the matrix (that is, the first layer 123a forms the matrix, and the nanostructures 123c form the second layer 123b buried within the matrix. Because the nanostructures 123c are apart from each other, the nanostructures 123c may function as independent charge trap media. Charges introduced into the charge storage layer 123 from the channel layer 121 through the charge tunneling layer 122 are trapped in the nanostructures 123c. Because the nanostructures 123c are ferroelectric, the second layer 123b formed by the nanostructures 123c provides a new type of charge storage defect structure, and thus, the trap density of the nanostructures 123c may be improved. Therefore, charges are primarily trapped in the nanostructures 123c, and the trap density of the nanostructures 123c is greater than the trap density of the first layer 123a.

Lateral charge migration occurs in the longitudinal direction z of the charge storage layer 123 when charges move along the nanostructures 123c in the longitudinal direction z. In at least one example embodiment, charges (for example, electrons) are trapped in the nanostructures 123c but are rarely trapped between the nanostructures 123c that are arranged apart from each other. Therefore, the trap density of the nanostructures 123c is significantly greater than the trap density of the matrix, and the trap density in the longitudinal direction z of the charge storage layer 123 is discontinuous depending on the arrangement of the nanostructures 123c. Because the nanostructures 123c having a relatively high trap density are spatially apart from each other, it is difficult for charges to migrate between two adjacent nanostructures 123c. Therefore, trap-assisted conduction is suppressed, and thus, lateral migration of charges may be reduced. Furthermore, the matrix provided between the nanostructures 123c acts as a barrier to lateral migration of charges in the longitudinal direction z of the charge storage layer 123, and thus, lateral migration of charges may be further reduced.

Additionally, because the matrix is provided between the nanostructures 123c that trap charges and between the nanostructures 123c and the charge tunneling layer 122, the matrix acts as a barrier against charge migration occurring from the charge storage layer 123 to the charge tunneling layer 122 by trap-assisted tunneling or thermal emission. Therefore, migration of charges trapped in the nanostructures 123c may be reduced or prevented in directions perpendicular to the charge storage layer 123, that is, in the x-axis direction and/or the y-axis direction.

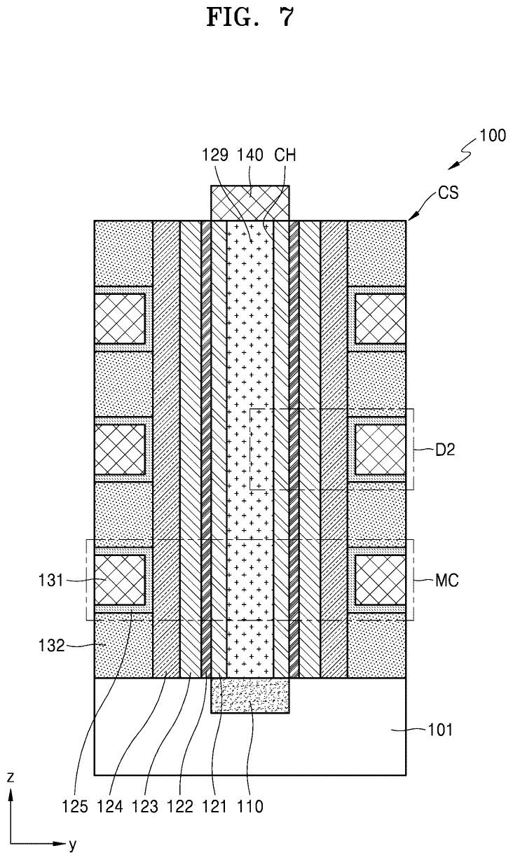

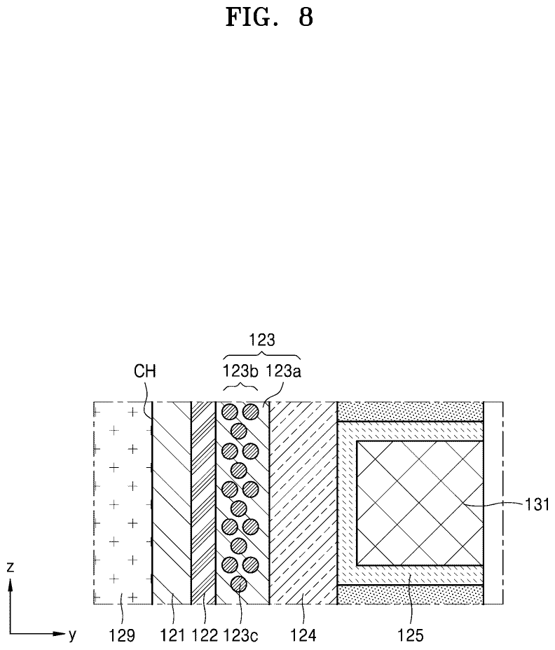

FIG. 7 is a schematic cross-sectional view illustrating a vertical nonvolatile memory device 100 according to at least one example embodiment, and FIG. 8 is an enlarged view illustrating a portion D2 in FIG. 7. The vertical nonvolatile memory device 100 of at least one example embodiment differs from the vertical nonvolatile memory devices 100 of the embodiments shown in FIGS. 1 to 6 in that the vertical nonvolatile memory device 100 of at least one example embodiment further includes diffusion prevention layers 125. Therefore, unless otherwise contradicted, the descriptions of FIGS. 1 to 6 apply to the vertical nonvolatile memory device 100 of at least one example embodiment shown in FIGS. 7 and 8. FIG. 8 illustrates a charge storage layer 123 of the type shown in FIG. 6 as an example. However, the charge storage layers 123 shown in FIGS. 3 to 5 may be applied to the vertical nonvolatile memory device 100 of at least one example embodiment. In the drawings, like reference numerals denote like elements, and repeated descriptions thereof are omitted. The following description focuses on the differences from the previous embodiments.

Referring to FIGS. 7 and 8, the diffusion prevention layers 125 is between a charge blocking layer 124 and gate electrodes 131. The diffusion prevention layers 125 may also be arranged between the gate electrodes 131 and isolation layers 132. The diffusion prevention layers 125 may prevent interfacial reaction and atomic diffusion between a charge storage layer 123 and the gate electrodes 131. The diffusion prevention layers 125 may further enhance adhesion between two adjacent material layers, such as adhesion between the charge blocking layer 124 and the gate electrodes 131 and adhesion between the gate electrodes 131 and the isolation layers 132. The diffusion prevention layers 125 may reduce electrical resistance at contact surfaces between two material layers, thereby protecting against power loss, temperature rise, and degradation of the operational characteristics of the vertical nonvolatile memory device 100. The diffusion prevention layers 125 may include a material having a greater redox potential than a material of the isolation layers 132. For example, the diffusion prevention layers 125 may include a material having a greater redox potential than silicon oxide. The diffusion prevention layers 125 may include at least one of titanium (Ti), zirconium (Zr), vanadium (V), aluminum (Al), lanthanum (La), niobium (Nb), or tantalum (Ta), and/or may include a nitride including at least one of the listed elements. For example, the diffusion prevention layers 125 may include at least one of TiN or NbN.

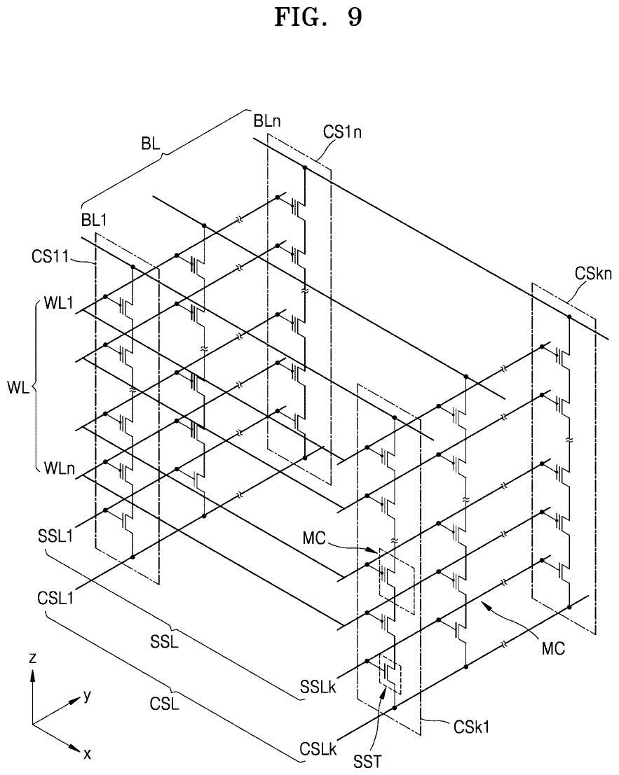

FIG. 9 illustrates a circuit diagram including a vertical nonvolatile memory device according to at least one example embodiment. k*n cell strings CS may be arranged in a matrix form and may be named CSij (1≤i≤k, 1≤j≤n) based on row and column positions. Each of the cell strings CSij may be connected to a bit line BL, a string select line SSL, word lines WL, and a common source line CSL. Each of the cell strings CSij includes memory cells MC and a string select transistor SST. The memory cells MC and the string select transistor SST of each of the cell strings CSij may be stacked in a height direction.

Rows of the cell strings CS may be connected to different string select lines SSL1 to SSLk. For example, the string select transistors SST of the cell strings CS11 to CS1n may be commonly connected to the string select line SSL1. The string select transistors SST of the cell strings CSk1 to CSkn may be commonly connected to the string select line SSLk.

Columns of the cell strings CS are connected to different bit lines BL1 to BLn. For instance, the memory cells MC and the string select transistors SST of the cell strings CS11 to CSk1 may be commonly connected to the bit line BL1, and the memory cells MC and the string select transistors SST of the cell strings CS1n to CSkn may be commonly connected to the bit line BLn.

Rows of the cell strings CS may be connected to different common source lines CSL1 to CSLk. For example, the string select transistors SST of the cell strings CS11 to CS1n may be commonly connected to the common source line CSL1, and the string select transistors SST of the cell strings CSk1 to CSkn may be commonly connected to the common source line CSLk.

Memory cells MC arranged at the same height from a substrate 101 (refer to FIG. 1) or the string select transistors SST may be commonly connected to one word line WL, and memory cells MC arranged at different heights may be connected to different word lines WL1 to WLn.

The circuit structure shown in FIG. 9 is only an example. For instance, the number of rows of the cell strings CS may be increased or decreased As the number of rows of the cell strings CS varies, the number of string select lines SSL connected to the rows of the cell strings CS and the number of cell strings CS connected to each of the bit lines BL may also vary. As the number of rows of the cell strings CS varies, the number of common source lines CSL connected to the rows of the cell strings CS may also vary.

The number of columns of the cell strings CS may be increased or decreased. As the number of columns of the cell strings CS varies, the number of bit lines BL connected to the columns of the cell strings CS and the number of cell strings CS connected to each of the string select lines SSL may also vary.

The height of the cell strings CS may also be increased or decreased. For example, the number of memory cells MC stacked in each of the cell strings CS may be increased or decreased. As the number of memory cells MC stacked in each of the cell strings CS varies, the number of word lines WL may also vary. For example, the number of string select transistors SST provided in each of the cell strings CS may be increased. As the number of string select transistors SST provided in each of the cell strings CS varies, the number of string select lines SSL or the number of common source lines CSL may also vary. When the number of string select transistors SST increases, the string select transistors SST may be stacked in the same manner as the memory cells MC.

For example, writing and reading may be performed in units of rows of the cell strings CS. The cell strings CS may be selected in units of rows through the common source lines CSL. The cell stings CS may also be selected in units of rows through the string select lines SSL. In addition, a voltage may be applied to the common source lines CSL in units of at least two common source lines CSL. Alternatively, a voltage may be applied to all the common source lines CSL by treating all the common source lines CSL as a single unit.

In a selected row of the cell strings CS, writing and reading may be performed in units of pages. A page may refer to a row of memory cells MC connected to one word line WL. In a selected row of the cell strings CS, memory cells MC may be selected in units of pages by the word lines WL. For example, each of the gate electrodes 131 shown in FIGS. 1 and/or 7 may be connected to one of the word lines WL or string select lines SSL.

Each of the memory cells MC has a circuit structure in which a transistor including a gate electrode 131, an isolation layer 132, and a channel layer 121 is connected to a charge storage layer 123.

Each of the cell strings CS is formed by memory cells MC continuously arranged in a vertical direction (z-axis direction). As shown in the circuit diagram of FIG. 9, both ends of each of the cell strings CS may be connected to a common source line CSL and a bit line BL, respectively. Programming, reading, and erasing may be performed on a plurality of memory cells MC by applying a voltage to a common source line CSL and a bit line BL.

For example, when a memory cell MC targeted for writing is selected, a gate voltage of the selected memory cell MC is adjusted to prevent channel formation, that is, to bring the selected memory cell MC into a channel-off state, and gate voltages of unselected memory cells MC are adjusted to bring the unselected memory cells MC into a channel-on state. As a result, charge may tunnel through a charge tunneling layer 122 and become trapped in a charge storage layer 123 of the selected memory cell MC due to a voltage applied to a common source line CSL and a bit line BL, and thus, intended data (1 or 0) may be recorded in the selected memory cell MC.

During a read operation, a selected memory cell MC may be read in a similar manner. That is, after adjusting gate voltages applied to gate electrodes 131 of memory cells CS to turn off a channel of the selected memory cell MC and turn on channels of unselected memory cells MC, a current flowing through the selected memory cell MC may be measured using a voltage Vread applied between a common source line CSL and a bit line BL to determine the state (1 or 0) of the selected memory cell MC.

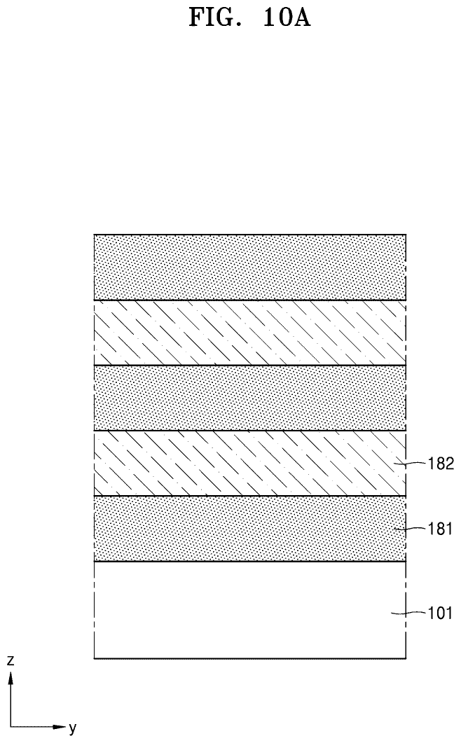

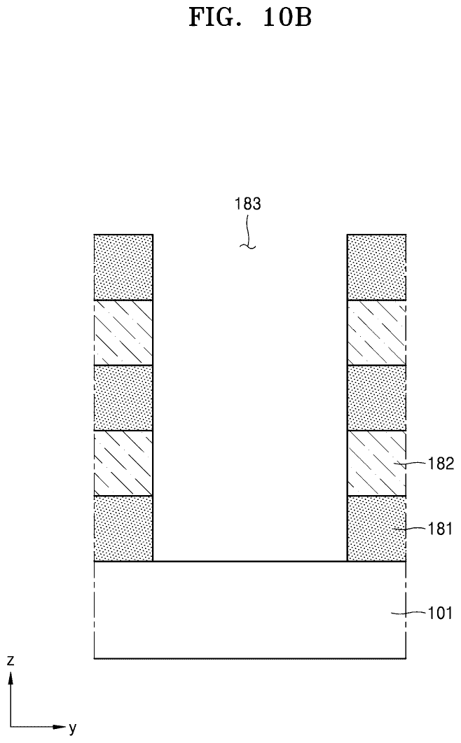

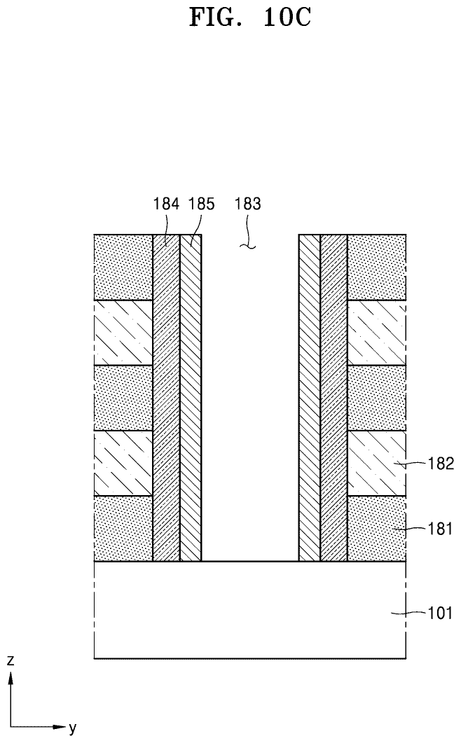

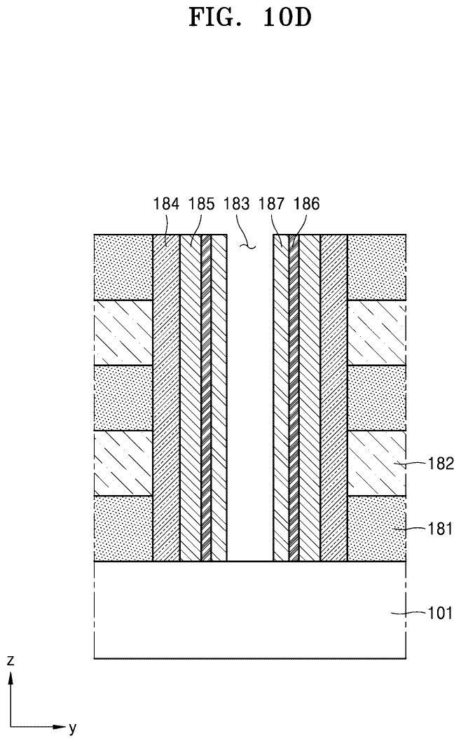

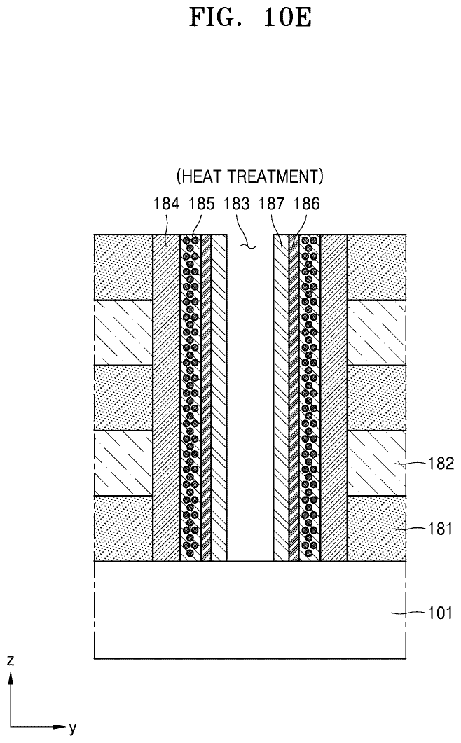

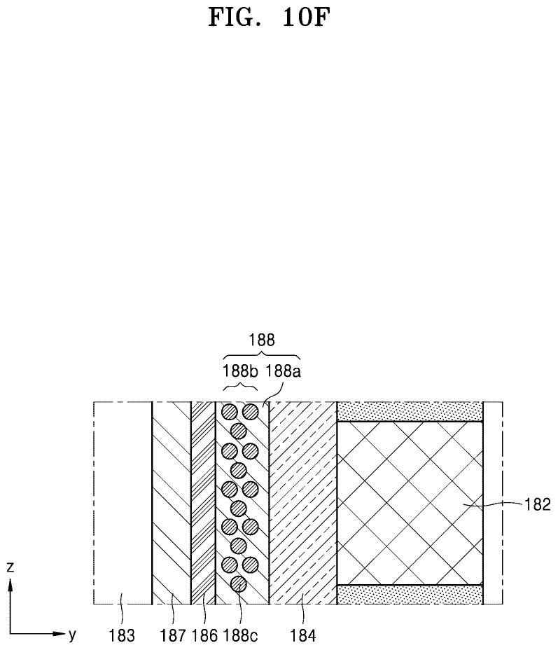

A method of manufacturing the vertical nonvolatile memory device shown in FIG. 6 will now be described according to embodiments. FIGS. 10A to 10F illustrate a method of manufacturing a vertical nonvolatile memory device according to at least one example embodiment.

First, referring to FIG. 10A, a substrate 101 is prepared. For example, the substrate 101 may include a single-crystal silicon substrate, a compound semiconductor substrate, or an SOI substrate, but is not limited thereto. In addition, the substrate 101 may further include dopant regions formed by doping, electronic devices such as transistors, and/or a peripheral circuit configured to select and control memory cells for storing data.

Next, insulating layers 181 and conductive layers 182 are alternately stacked on the substrate 101. The insulating layers 181 may include, for example, at least one of silicon oxide, silicon nitride, or the like, but are not limited thereto. The conductive layers 182 may include, for example, at least one of a highly electrically conductive metal such as gold (Au) or silicon doped with a dopant, but are not limited thereto. The insulating layers 181 and the conductive layers 182 may be formed by various deposition methods such as chemical vapor deposition (CVD), ALD, physical vapor deposition (PVD), and/or the like.

Next, referring to FIG. 10B, a channel hole 183 is formed through the insulating layers 181 and the conductive layers 182. Here, the channel hole 183 may extend in a direction perpendicular to a surface of the substrate 101. The channel hole 183 may extend to an upper surface of the substrate 101. For example, the channel hole 183 may have a cylindrical shape, but is not limited thereto. The channel hole 183 may be formed by anisotropically etching the insulating layers 181 and the conductive layers 182.

Next, referring to FIG. 10C, a charge blocking layer 184 is formed on an inner wall of the channel hole 183. The charge blocking layer 184 may extend in the direction perpendicular to the surface of the substrate 101. The charge blocking layer 184 may be formed on the inner wall of the channel hole 183 such that the charge blocking layer 184 may be in contact with the insulating layers 181 and the conductive layers 182. The charge blocking layer 184 may be formed in a cylindrical shape. The charge blocking layer 184 may be formed by depositing silicon oxide, a metal oxide, or a metal nitride on the inner wall of the channel hole 183 through ALD.

Next, a mixture layer 185 is formed on an inner side the charge blocking layer 184. The mixture layer 185 may include Si, N, Al, and at least one dopant selected from Sc, B, Sn, Ga, Hf, Zr, and Ti. The mixture layer 185 may be formed by sputtering, MOCVD, ALD, THALD, and/or the like. A first cycle for providing Al and Si and a second cycle for providing a dopant may be repeated with timing and rate based on the ratio of the dopant contents of a first layer 123a and a second layer 123b (described later). The distribution of Si, Al, and dopant contents of the mixture layer 185 in the thickness direction of the mixture layer 185 may be determined to satisfy R≤0.4 and/or about 0.05≤R≤about 0.2 in A_{1-R}D_{R}N such that when a matrix and nanostructures are formed through a heat treatment process (described later), the matrix (amorphous matrix) may exhibit general dielectric characteristics. The mixture layer 185 may have a metastable mixed phase.

Referring to FIG. 10D, a charge tunneling layer 186 is formed on a surface of the mixture layer 185. The charge tunneling layer 186 may be formed by depositing, for example, silicon oxide or a metal oxide on an inner wall of the mixture layer 185 through ALD. Next, a channel layer 187 is formed on a surface of the charge tunneling layer 186. The channel layer 187 may be formed by depositing a semiconductor material on an inner wall of the charge tunneling layer 186 through ALD. Although not shown in FIG. 10D, a dielectric material such as silicon oxide may be deposited inside the channel layer 187 to fill the channel hole 183. However, embodiments are not limited thereto, and the channel hole 183 may be filled with air.

Referring to FIGS. 10E and 10F, the structure shown in FIG. 10D is heat treated at a treatment temperature. The heat treatment temperature may be from about 800° C. to about 1300° C., and may be from about 900° C. to about 1100° C. The treatment temperature of the heat treatment is selected to cause spinodal decomposition in the mixture layer 185 and additionally nucleation growth in the mixture layer 185, thereby forming nanostructures 188c. In other words, the mixture layer 185 is a type of solid solution, and due to the thermodynamic instability of the solid solution, the nanostructures 188c and a matrix 188a may be formed. The matrix 188a and the nanostructures 188c correspond to the first layer 123a and the nanostructures 123c in the embodiment shown in FIG. 6. The nanostructures 188c may have a diameter of about 3 nm to about 4 nm and do not form interfaces with adjacent layers, that is, the charge blocking layer 184 and the charge tunneling layer 186. The nanostructures 188c are embedded within the matrix 188a, forming an insertion layer 188b that is apart from the charge tunneling layer 186 and the charge blocking layer 184. The insertion layer 188b corresponds to the second layer 123b shown in FIG. 6. The nanostructure 188c may function as independent charge trap media.

The nanostructures 188c may have various shapes, such as at least one of a spherical shape, an elliptical shape, a disk shape, a rod shape, or an irregular shape The shape and size of the nanostructures 188c may be controlled according to the temperature of the heat treatment. The shape, size, and distribution of the nanostructures 188c may be analyzed using, for example, at least one of transmission electron microscopy (TEM), X-ray diffraction (XRD), or photoluminescence (PL) spectroscopy. The matrix 188a may have an amorphous structure, and the nanostructures 188c may have a crystalline or amorphous structure. When the nanostructures 188c have a crystalline structure, the nanostructures 188c may be referred to as nanocrystals.

The description above is of an example in which the heat treatment is performed on the structure shown in FIG. 10D to cause spinodal decomposition. However, the heat treatment for spinodal decomposition is not limited thereto and may be performed in any manufacturing process after forming the mixture layer 185.

The insulating layers 181 serve as isolation layers, and the conductive layers 182 serve as gate electrodes. When other insulating layers are formed instead of the conductive layers 182, an additional process may be performed to form gate electrodes. For example, in the structure shown in FIG. 10E, a process for selectively removing the conductive layers 182 may be performed. Then, openings through which the charge blocking layer 184 is exposed are formed between the insulating layers 181. Gate electrodes opposite the channel layer 187 may be formed by filling the openings with a conductive material. As described above, the vertical nonvolatile memory device shown in FIG. 6 may be manufactured. Additionally, a pillar 129 may be deposited into a remaining portion of the channel hole 183.

The vertical nonvolatile memory devices of the embodiments described above may be applied to various electronic apparatuses.

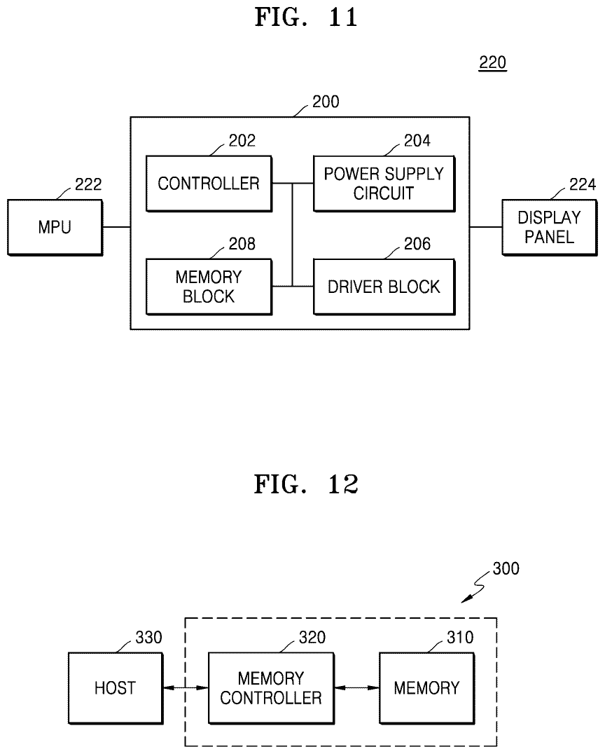

FIG. 11 is a schematic block diagram illustrating a display driver integrated circuit (display driver IC or DDI) 200 and a display apparatus 220 including the DDI 200 according to at least one example embodiment. Referring to FIG. 11, the DDI 200 may include a controller 202, a power supply circuit 204, a driver block 206, and a memory block 208. The controller 202 may be configured to receive and decode a command applied from a main processing unit (MPU) 222 and control each of the blocks of the DDI 200 to implement an operation according to the command. The power supply circuit 204 may be configured to generate a driving voltage in response to control by the controller 202. The driver block 206 may be configured to drive a display panel 224 by using the driving voltage generated by the power supply circuit 204 in response to the control by the controller 202. The display panel 224 may be, for example, a liquid crystal display panel, an organic light emitting device (OLED) display panel, or a plasma display panel. The memory block 208 may be a block configured to temporarily store commands input to the controller 202 or control signals output from the controller 202 or storing desired data and may include a memory such as a random access memory (RAM) and/or a ready-only memory (ROM). For example, the memory block 208 may include any of the vertical nonvolatile memory devices 100 of the embodiments described above.

FIG. 12 is a block diagram illustrating an electronic apparatus 300 according to at least one example embodiment. Referring to FIG. 12, the electronic apparatus 300 may include a memory 310 and a memory controller 320. The memory controller 320 may be configured to control the memory 310 to read data from the memory 310 and/or write data into the memory 310 in response to a request from a host 330. The memory 310 may include any of the vertical nonvolatile memory devices 100 of the embodiments described above.

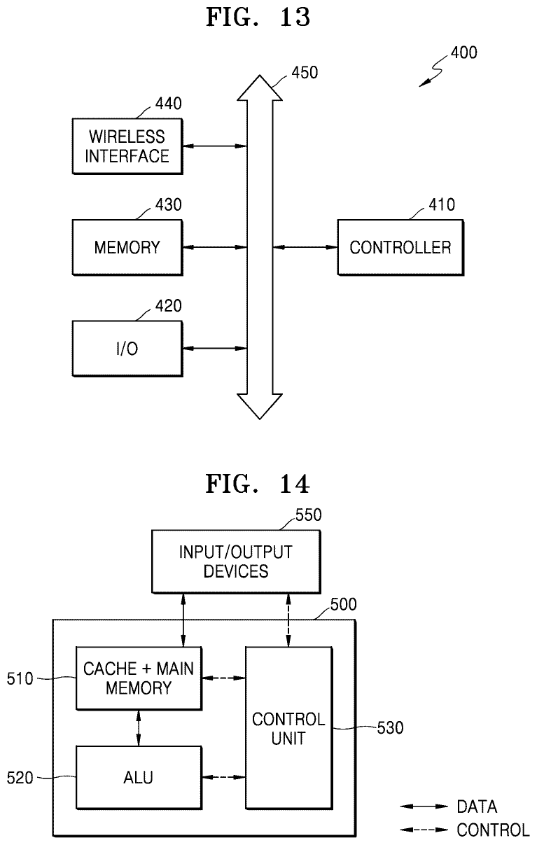

FIG. 13 is a block diagram illustrating an electronic apparatus 400 according to at least one example embodiment. Referring to FIG. 13, the electronic apparatus 400 may be configured to form a wireless communication apparatus and/or an apparatus be configured to transmit and/or receive information in a wireless environment. The electronic apparatus 400 may include a controller 410, an input/output (I/O) device 420, a memory 430, and a wireless interface 440, which may be connected to each other through a bus 450.

The controller 410 may include at least one of a microprocessor, a digital signal processor, and any similar processing device. The I/O device 420 may include at least one of a keypad, a keyboard, and a display. The memory 430 may be used to store a command executed by the controller 410. For example, the memory 430 may be used to store user data. The electronic apparatus 400 may use the wireless interface 440 to transmit/receive data through a wireless communication network. The wireless interface 440 may include an antenna and/or a wireless transceiver. In some embodiments, the electronic apparatus 400 may be used in the communication interface protocols of third-generation communication systems such as Code Division Multiple Access (CDMA), Global System for Mobile Communications (GSM), North American Digital Cellular (NADC), Extended Time Division Multiple Access (E-TDMA), and/or Wideband Code Division Multiple Access (WCDMA). The memory 430 of the electronic apparatus 400 may include any of the vertical nonvolatile memory devices 100 of the embodiments described above.

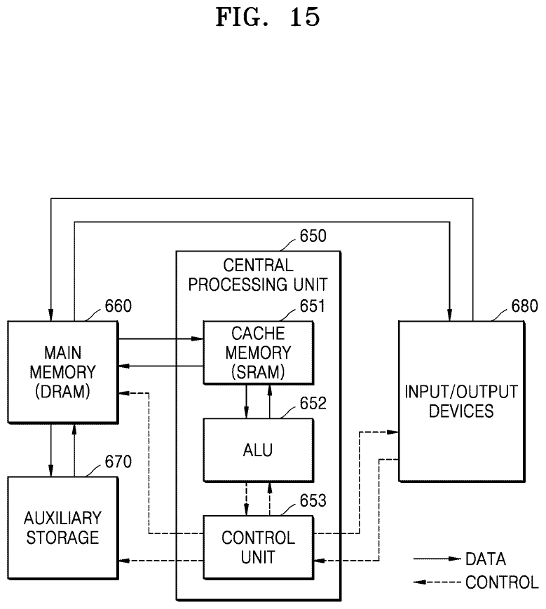

FIGS. 14 and 15 are conceptual diagrams schematically illustrating device architectures applicable to an electronic apparatus according to embodiments.

Referring to FIG. 14, an electronic apparatus architecture 500 may include a memory unit 510 and a control unit 530 and may further include an arithmetic logic unit (ALU) 520. The memory unit 510, the ALU 520, and the control unit 530 may be electrically connected to each other. For example, the electronic apparatus architecture 500 may be implemented as a single chip including the memory unit 510, the ALU 520, and the control unit 530. For example, the memory unit 510, the ALU 520, and the control unit 530 may be connected to each other through metal lines on a chip to directly communicate with each other. The memory unit 510, the ALU 520, and the control unit 530 may be monolithically integrated on one substrate 101 (refer to FIG. 1) to form one chip. An input/output device 550 may be connected to the electronic apparatus architecture (chip) 500. In addition, the memory unit 510 may include both a main memory and a cache memory. The electronic apparatus architecture (chip) 500 may be an on-chip memory processing unit. Each of the memory unit 510, the ALU 520, and/or the control unit 530 may independently include any of the vertical nonvolatile memory devices (100) of the embodiments described above.

Referring to FIG. 15, a cache memory 651, an ALU 652, and a control unit 653 may form a central processing unit (CPU) 650, and the cache memory 651 may include a static random access memory (SRAM). Separately from the CPU 650, a main memory 660 and an auxiliary storage 670 may be provided and an input/output device 680 may also be provided. The main memory 660 may be, for example, a dynamic random access memory (DRAM) and may include any of the vertical nonvolatile memory devices (100) of the embodiments described above.

In some cases, the electronic apparatus architecture 500 may be implemented as a single chip in which computing unit devices and memory unit devices are adjacent to each other in one chip without distinction between subunits.

The vertical nonvolatile memory devices (100) of the embodiments may be applied to various user devices such as computers, portable computers, ultra mobile PCs (UMPCs), workstations, netbooks, PDAs, portable computers, web tablets, wireless phones, mobile phones, smartphones, digital cameras, digital audio recorders, digital audio players, digital picture recorders, digital picture players, digital video recorders, digital video players, devices capable of transmitting and receiving information in a wireless environment, and home networks.

According to a memory device according to one or more embodiments, a nitride ferroelectric is included in a charge storage layer, and thus, an operating voltage of the memory device may be reduced.

According to the memory device according to one or more embodiments, the matrix-nitride ferroelectric are included in the charge storage layer, and thus, charge retention of the memory device may be improved.

According to a method of manufacturing a vertical nonvolatile memory device, according to one or more embodiments, a charge storage layer including matrix-nitride ferroelectric nanostructures may be formed through heat treatment.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A vertical nonvolatile memory device comprising:
a plurality of cell strings, each of the plurality of cell strings including
a plurality of layers including a channel layer, a charge tunneling layer, a charge storage layer, and a charge blocking layer sequentially arranged in a transverse direction such that the charge blocking layer is an outer most layer of the plurality of layers, the transverse direction perpendicular to a longitudinal direction;
a plurality of gate electrodes located outside the charge blocking layer and arranged in the longitudinal direction; and
a plurality of isolation layers arranged in the longitudinal direction and isolating the plurality of gate electrodes from each other,
wherein the charge storage layer comprises a first layer and a second layer, the first layer comprising Si and N, and the second layer comprising a nitride ferroelectric.

2. The vertical nonvolatile memory device of claim 1, wherein the nitride ferroelectric comprises at least one selected from AlN, ZnSiN₂, or MgSiN₂.

3. The vertical nonvolatile memory device of claim 1, wherein the nitride ferroelectric comprises AlN, and
the second layer is doped with at least one dopant selected from Sc, B, Sn, Ga, Hf, Zr, or Ti.

4. The vertical nonvolatile memory device of claim 3, wherein a content of the at least one dopant in the second layer is 40% or less.

5. The vertical nonvolatile memory device of claim 3, wherein a content of the at least one dopant in the second layer is about 5% to about 20%.

6. The vertical nonvolatile memory device of claim 2, wherein the second layer has a wurtzite structure.

7. The vertical nonvolatile memory device of claim 1, wherein a thickness of the second layer is about 15% to about 50% of a thickness of the charge storage layer.

8. The vertical nonvolatile memory device of claim 1, wherein the second layer is between the charge tunneling layer and the first layer.

9. The vertical nonvolatile memory device of claim 1, wherein the second layer is between the charge blocking layer and the first layer.

10. The vertical nonvolatile memory device of claim 1, wherein the charge storage layer includes two or more of the second layers, and one of the second layers is between the charge tunneling layer and the first layer and another of the second layers is between the charge blocking layer and the first layer.

11. The vertical nonvolatile memory device of claim 1, wherein the second layer is within the first layer such that the second layer is not in contact with either the charge tunneling layer or the charge blocking layer.

12. The vertical nonvolatile memory device of claim 11, wherein
the first layer forms an amorphous matrix, and
the nitride ferroelectric forms a plurality of nanostructures.

13. The vertical nonvolatile memory device of claim 12, wherein the plurality of nanostructures are apart from each other.

14. The vertical nonvolatile memory device of claim 12, wherein the plurality of nanostructures have a wurtzite structure.

15. The vertical nonvolatile memory device of claim 12, wherein the amorphous matrix comprises Si, N, Al, and at least one dopant selected from Sc, B, Sn, Ga, Hf, Zr, or Ti, and
the nitride ferroelectric comprises Al and N and at least one dopant selected from Sc, B, Sn, Ga, Hf, Zr, or Ti.

16. The vertical nonvolatile memory device of claim 15, wherein a content of the at least one dopant in the second layer is 40% or less.

17. The vertical nonvolatile memory device of claim 15, wherein a content of the at least one dopant in the second layer is about 5% to about 20%.

18. An electronic apparatus comprising:
a memory; and
a memory controller configured to control the memory to read data from the memory and to write data to the memory,
wherein the memory comprises the vertical nonvolatile memory device of claim 1.

19. A method of manufacturing a memory device, the method comprising:
alternately stacking insulating layers and conductive layers on a substrate;
forming a channel hole through the insulating layers and the conductive layers;
forming a charge blocking layer in the channel hole;
forming a charge storage layer on an inner wall of the charge blocking layer;
forming a charge tunneling layer on the charge storage layer; and
forming a channel layer on the charge tunneling layer,
wherein the forming of the charge storage layer comprises
forming a mixture layer on an inner wall of the charge blocking layer, the mixture layer comprising Si, N, Al, and at least one dopant selected from Sc, B, Sn, Ga, Hf, Zr, or Ti, and
forming a first layer and a second layer by heat treating the mixture layer, the first layer comprising an amorphous matrix comprising Si, N, Al, and at least one dopant selected from Sc, B, Sn, Ga, Hf, Zr, and Ti, the second layer comprising a plurality of nanostructures apart from each other, the plurality of nanostructures having a wurtzite structure comprising Al, N, and at least one dopant selected from Sc, B, Sn, Ga, Hf, Zr, and Ti, and the second layer being within the amorphous matrix such that the second layer is not in contact with either the charge tunneling layer or the charge blocking layer.

20. The method of claim 19, wherein a content of the at least one dopant in the second layer is 40% or less.
